(19) United States
(12) Patent Application Publication
(10) Pub. No.: US 2013/0089981 A1
(43) Pub. Date: Apr. 11, 2013

(54) METHOD OF MANUFACTURING SEMICONDUCTOR DEVICE

(71) Applicant: ELPIDA MEMORY, INC., Tokyo (JP)

(72) Inventor: Kenichi KUSUMOTO, Tokyo (JP)

(73) Assignee: ELPIDA MEMORY, INC., Tokyo (JP)

(21) Appl. No.: 13/645,005

(22) Filed: Oct. 4, 2012

(30) Foreign Application Priority Data
Oct. 6, 2011 (JP) 2011-222095

(51) Int. Cl. H01L 21/302

(52) U.S. Cl. 438/660; 257/E21.214

(57) ABSTRACT

The invention provides a method of manufacturing a semiconductor device, capable of forming, on a silicon layer, a nickel mono-silicide layer having a low resistance value and a desirable flatness. The method includes depositing a platinum-containing nickel layer that covers the silicon layer formed on the substrate, and that has crystallinity lower in a portion thereof close to the silicon layer than in a portion remote from the silicon layer, and forming a nickel mono-silicide layer at the interface between the silicon layer and the platinum-containing nickel layer by heating the substrate.

This application is based upon and claims the benefit of priority from Japanese patent application No. 2011-222095, filed on Oct. 6, 2011, the disclosure of which is incorporated herein in its entirety by reference.

### BACKGROUND OF THE INVENTION

This invention relates to a method of manufacturing a semiconductor device.

Japanese Patent Application Publication Nos. H08-255769 (Patent Document 1), 2008-78559 (Patent Document 2), and 2009-176975 (Patent Document 3) disclose processes of forming a nickel silicide layer on a silicon layer by a salicide (Self-ALIgned siliCide) method. Specifically, a nickel (Ni) layer is deposited on a surface on which silicon is exposed and is heated to cause a silicide reaction to occur in a contact surface, namely, an interface between Si and Ni layers and, as a result, a nickel silicide layer is formed. Thereafter, any un-reacted Ni is selectively removed.

Thus, these Patent Documents disclose processes of forming a nickel silicide layer by a so-called salicide method wherein NiSi is formed in a self-aligned manner on an exposed silicon surface.

### SUMMARY OF THE INVENTION

More specifically, Patent Document 2 discloses that the nickel silicide phase composition is rendered into a phase of di-nickel silicide (Ni₂Si) (namely, di-nickel silicide (Ni₂Si) phase)when heated at a temperature of 120 to 280° C., whereas it is rendered into a phase of nickel mono-silicide (NiSi) (namely, nickel mono-silicide (NiSi) phase) when heated at a temperature of 300° C. or higher.

Nickel mono-silicide is lower in electric resistance than di-nickel silicide. Therefore, if the nickel silicide is not heated sufficiently, the nickel silicide cannot be completely rendered into to nickel mono-silicide and results in high resistance.

According to experimental studies of the inventor, it has found out that a long heat treatment at a high temperature (e.g. 400 to 600° C.) causes the nickel di-silicide (NiSi₂) phase to occur and the nickel di-silicide phase is thermally very stable.

However, the nickel di-silicide phase is lower in flatness as compared with the nickel mono-silicide phase. Therefore, excessive heat treatment brings about a local aggregation of the nickel di-silicide phase, resulting in irregularity in shape.

Thus, in order to form nickel mono-silicide of low electric resistance, the heat treatment process must be devised such that phase is not transformed to a nickel di-silicide phase that is thermally stable but is low in flatness, and/or such that di-nickel silicide of a high resistance value can be rendered into nickel-monosilicide as much as possible.

For example, Patent Document 2 discloses a technique in which Pt-containing Ni is used to control the silicide reaction caused by a heat treatment. It also discloses annealing conditions, the annealing times to be performed, and a combination of methods for removing the Ni film containing unreacted Pt.

The inventor has studied the method of forming nickel silicide by the salicide technique disclosed in Patent Document 2, and found that although the method makes it possible to form nickel mono-silicide having a low resistance value, uniform interface configuration with Si can not be obtained and hence the method should be improved more in terms of the flatness.

According to an aspect of the invention, there is obtained a method of manufacturing a semiconductor device, including depositing a platinum-containing nickel layer that covers the silicon layer formed on the substrate, and that has crystallinity lower in a portion of the platinum-containing nickel layer close to the silicon layer than in a portion remote from the silicon layer, and forming a nickel mono-silicide layer at the interface between the silicon layer and the platinum-containing nickel layer by heating the substrate.

### EFFECT OF THE INVENTION

According to the method of manufacturing a semiconductor device of the invention, it is made possible to control the silicide reaction by depositing a platinum-containing nickel layer that has the crystallinity lower in a portion close to a silicon layer than in a portion remote from the silicon layer. This means that the silicide reaction can be realized evenly (uniformly) all over a predetermined area (area where the silicon layer is exposed).

As a result, it is made possible to form a nickel mono-silicide layer having a low resistance value such that the nickel silicide will not be transformed to a nickel di-silicide phase which is thermally stable (but has a poor surface smoothness) and such that the di-nickel silicide having a high resistance value is transformed into nickel-monosilicide as much as possible.

Further, the crystallinity can be rendered low at least in a portion close to the silicon layer by depositing the platinum-containing nickel in the portion close to the silicon layer so as to have a lower crystallinity than in a portion remote from the silicon layer.

This enables the silicide reaction to progress evenly (uniformly) in a predetermined area (area where the silicon layer is exposed) even after a silicidation reaction caused by heating of the substrate, and makes it possible to form a nickel mono-silicide layer having a favorable surface smoothness. As a result, a nickel mono-silicide layer having a low resistance value and having a favorable flatness can be formed on the silicon layer.

The term “lower crystallinity” as used herein specifies a state in which crystal lattice intervals are widely varied; a period of crystal lattice arrangement is longer; transition from intrinsic crystalline structure of nickel at a relevant temperature is greater; and/or crystalline distortion due to stress is greater, in comparison with nickel crystal.

### BRIEF DESCRIPTION OF THE DRAWINGS

FIG. 1 is a cross-sectional view (part 1) showing a manufacturing process of a semiconductor device according to a first embodiment of the invention and illustrating a cross section of a MIS (Metal Insulator Semiconductor) transistor formed on a substrate;

FIG. 2 is a cross-sectional view (part 2) showing a manufacturing process of the semiconductor device according to the first embodiment of the invention, and illustrating a cross section of the MIS transistor in which a platinum-containing nickel layer is deposited, and an enlarged cross section of the encircled regions A and B of the MIS transistor having the platinum-containing nickel layer deposited;

FIG. 3 is a cross-sectional view (part 3) showing a manufacturing process of the semiconductor device according to the first embodiment of the invention, and illustrating a cross section of the MIS transistor in which a nickel mono-silicide layer is formed and the platinum-containing nickel layer remains, and an enlarged cross section of the encircled regions A and B of the MIS transistor in which the nickel mono-silicide layer is formed and the platinum-containing nickel layer remains;

FIG. 4 is a cross-sectional view (part 4) showing a manufacturing process of the semiconductor device according to the first embodiment of the invention, and illustrating a cross section of the MIS transistor having a nickel mono-silicide layer formed therein, and an enlarged cross section of the encircled regions A and B of the MIS transistor having the nickel mono-silicide layer formed therein;

FIG. 5 is a cross-sectional view (part 5) showing the manufacturing process of the semiconductor device according to the first embodiment of the invention;

FIG. 6 is a flowchart showing some steps of a method of manufacturing the semiconductor device according to the first embodiment of the invention, from the step of forming a MIS transistor to the step of removing an unreacted Pt-containing nickel layer;

FIG. 7 is a cross-sectional view (part 1) showing a principal part of a MIS transistor having a charge storage structure;

FIG. 8 is a cross-sectional view (part 2) showing a principal part of a MIS transistor having a charge storage structure;

FIG. 9 is a cross-sectional view (part 3) showing a principal part of a MIS transistor having a charge storage structure;

FIG. 10 is a cross-sectional view (part 1) showing a manufacturing process of a semiconductor device according to a second embodiment of the invention, and illustrating a cross section of a MIS transistor in which a di-nickel silicide layer is formed and a platinum-containing nickel layer remains, and an enlarged cross section of the encircled regions A and B of the MIS transistor in which the di-nickel silicide layer is formed and the platinum-containing nickel layer remains;

FIG. 11 is a cross-sectional view (part 2) showing the manufacturing process of the semiconductor device according to the second embodiment of the invention, and illustrating a cross section of the MIS transistor having a di-nickel silicide layer formed therein, and an enlarged cross section of the encircled regions A and B of the MIS transistor having the di-nickel silicide layer formed therein;

FIG. 12 is a cross-sectional view (part 3) showing the manufacturing process of the semiconductor device according to the second embodiment of the invention, and illustrating a cross section of the MIS transistor having a nickel mono-silicide layer formed therein, and an enlarged cross section of the encircled regions A and B of the MIS transistor having the nickel mono-silicide layer formed therein; and

FIG. 13 is a flowchart showing some steps of a method of manufacturing the semiconductor device according to the second embodiment of the invention, from the step of forming a MIS transistor to the step of forming a di-nickel silicide layer.

### DESCRIPTION OF EXEMPLARY EMBODIMENTS

Exemplary preferred embodiments of the invention will be described in detail with reference to the drawings. The drawings used in the following description are only for helping understanding of configurations of embodiments of the invention. The illustrated sizes, thicknesses, dimensions and the like of components shown in the drawings may be different from an actual dimensional relationship of the semiconductor device.

### First Embodiment

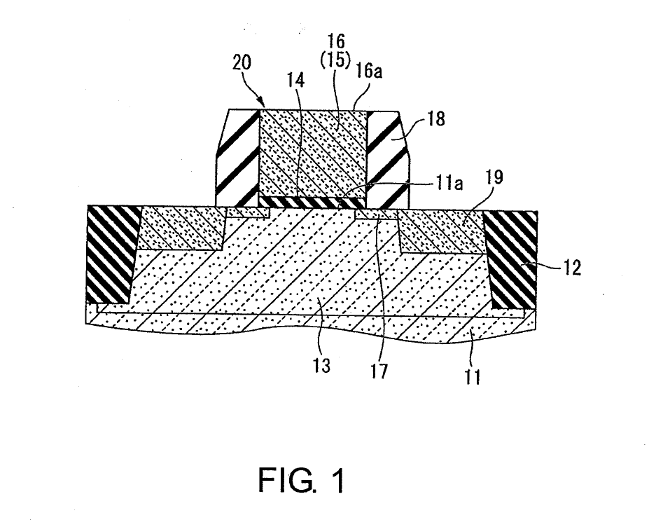

FIGS. 1 to 5 are cross-sectional views showing manufacturing processes of a semiconductor device according to a first embodiment of the invention. FIG. 1 is a diagram for explaining a process for forming a MIS (Metal Insulator Semiconductor) transistor 20, and illustrates a cross section of the MIS transistor 20 formed on a substrate 11.

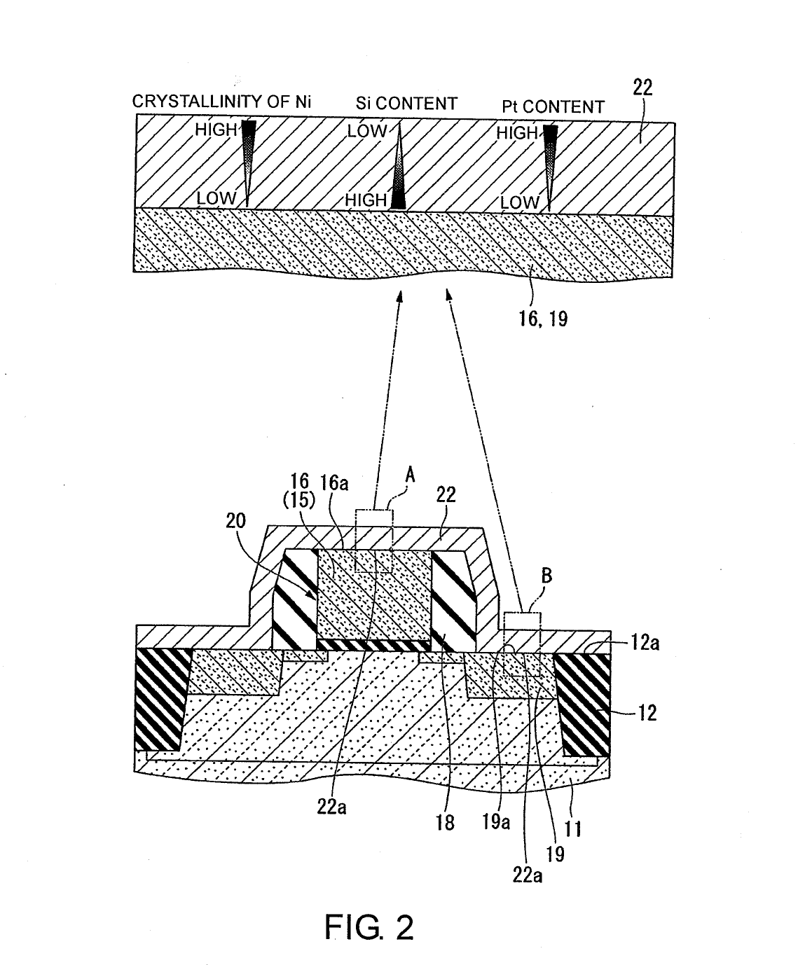

FIG. 2 is a cross-sectional view for explaining a process for depositing a platinum-containing nickel layer 22 on the structure shown in FIG. 1, and illustrates a cross section of the MIS transistor 20 having a platinum-containing nickel layer 22 deposited thereon, and an enlarged cross section of the encircled regions A and B in the MIS transistor 20 having the platinum-containing nickel layer 22 deposited thereon.

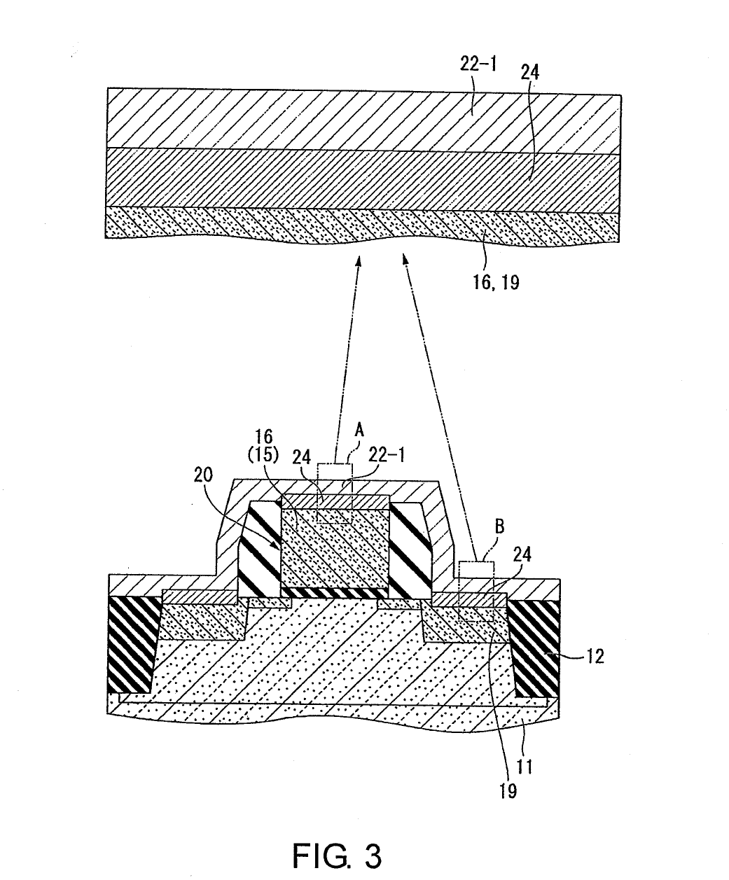

FIG. 3 is a cross-sectional view for explaining a process for forming a nickel mono-silicide layer 24, and illustrates a cross section of the MIS transistor 20 in which the nickel mono-silicide layer 24 is formed and a platinum-containing nickel layer 22-1 remains, and an enlarged cross section of the encircled regions A and B in the MIS transistor 20 in which the nickel mono-silicide layer 24 is formed and the platinum-containing nickel layer 22-1 still remains.

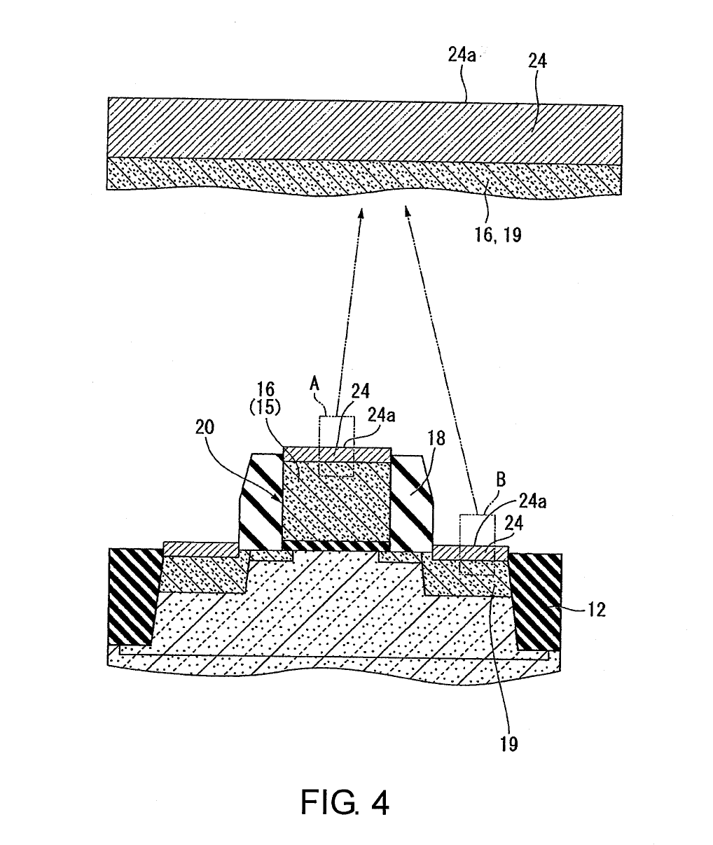

FIG. 4 is a cross-sectional view for explaining a process for removing the platinum-containing nickel layer 22-1, and illustrates a cross section of the MIS transistor 20 having the nickel mono-silicide layer 24 formed therein, and an enlarged cross section of the encircled regions A and B in the MIS transistor 20 having the nickel mono-silicide layer 24 formed thereon.

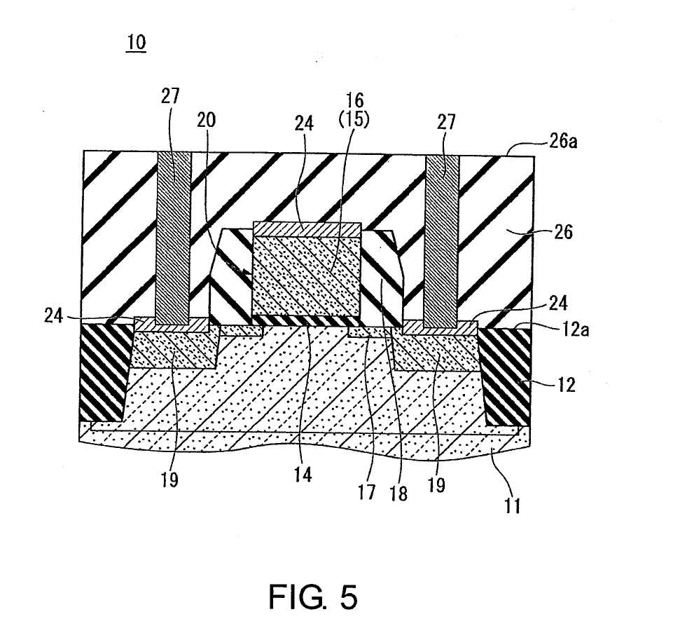

FIG. 5 is a cross-sectional view for explaining a process for forming an interlayer insulating film 26 and contact plugs 27 in the structure shown in FIG. 4.

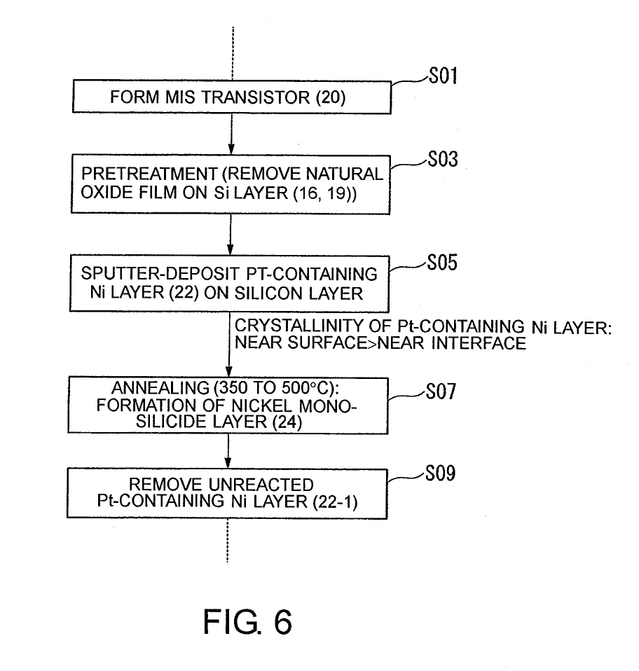

FIG. 6 is a flowchart showing some steps of a method of manufacturing a semiconductor device according to the first embodiment of the invention, from the step of forming a MIS transistor to the step of removing an un-reacted Pt containing nickel layer.

Referring to FIGS. 1 to 6, a method of manufacturing a semiconductor device 10 (see FIG. 5) according to the first embodiment will be described.

Firstly, in the process shown in FIG. 1, formation of a MIS transistor 20 (corresponding to step S01 in the flowchart of FIG. 6) is performed.

Specifically, in the process shown in FIG. 1, an element isolation region 12 is formed to define an active region in the substrate 11 by a known method (e.g. STI method). The substrate 11 (semiconductor substrate) may be, for example, a monocrystal silicon substrate composed of a silicon layer. The following description will be made in terms of an example in which a monocrystal silicon substrate is used as the substrate 11.

Subsequently, a well region 13 is formed in the active region by a known method. Next, an insulating film and a polysilicon film 15 (which is a silicon layer) are successively formed on the surface 11a of the substrate 11 as a base of a gate insulating film 14 and a base of a gate electrode 16, respectively.

Thereafter, the insulating film and the polysilicon film 15 are patterned by a photolithography technique and a dry etching technique to form a gate insulating film 14 and a gate electrode 16 integrally.

Subsequently, low-concentration impurity diffused regions 17 are formed by a known method in regions of the substrate 11 which are adjacent to side walls of the gate electrode 16 and which are opposite to each other. Subsequently, sidewall insulating films 18 are formed by a known method to cover the opposite side walls of the gate electrode 16.

Subsequently, a pair of high-concentration impurity diffused regions 19 (source/drain regions) are formed by implanting impurity ions into regions of the substrate 11 (in this example, a monocrystal silicon substrate) located between the element isolation region 12 and the low-concentration impurity diffused regions 17. Thus, the high-concentration impurity diffused regions 19 are composed of a silicon layer into which impurity ions are implanted.

As a result, a MIS capacitor 20 is formed which has the element isolation region 12, the well region 13, the gate insulating film 14, the gate electrode 16, the low-concentration impurity diffused regions 17, and the high-concentration impurity diffused regions 19.

In the process shown in FIG. 2, the step of exposing the silicon layer (corresponding to step S03 in the flowchart of FIG. 6), and the step of depositing a platinum-containing nickel layer 22 (corresponding to step S05 in the flowchart of FIG. 6) are performed sequentially.

In the process shown in FIG. 2, the step of exposing the silicon layer is performed as a pretreatment step before depositing a platinum-containing nickel layer. Specifically, physical or chemical removal is performed to remove a natural oxide film (silicon oxide (SiO₂) film formed by atmosphere exposure or chemical processing) (not shown) present on the top face 16a of the gate electrode 16 that is formed of a silicon layer and on the top faces 19a of the high-concentration impurity diffused regions 19 formed of a silicon layer in which impurity ions are implanted. As a result, the top face 16a of the gate electrode 16 and the top faces 19a of the high-concentration impurity diffused regions 19 are exposed.

Specifically, the physical removal is performed by an RF (radio frequency) etching method which uses argon (Ar) gas and which removes, by a sputter effect of an accelerated argon gas, the natural oxide film which is formed on the top face 16a of the gate electrode 16 and the top faces 19a of the high-concentration impurity diffused regions 19.

Alternatively, the chemical removal is performed by using a reactive gas, such as CF₄ gas, and by reacting the reactive gas with the natural oxide film formed on the top face 16a of the gate electrode 16 and the top faces 19a of the high-concentration impurity diffused regions 19. In this event, the natural oxide film is removed by sublimation of a reaction product.

Thereafter, a platinum-containing nickel layer 22 is deposited (to a thickness of 5 to 15 nm, for example) so as to cover the top face 16a of the gate electrode 16 and the top faces 19a of the high-concentration impurity diffused regions 19. Herein, it is to be noted that deposition of the platinum-containing nickel layer 22 is carried out so that the crystallinity of nickel is lower in a portion close to the top face 16a of the gate electrode 16 and the top faces 19a of the high-concentration impurity diffused regions 19 than in a portion remote from the top faces 16a and 19a (the step of depositing the platinum-containing nickel layer 22).

Thus, the platinum-containing nickel layer 22 is formed so as to cover the top face side of the structure shown in FIG. 1.

The wording “lower crystallinity of nickel” as used herein is featured by a state in which crystalline lattice intervals are widely varied; a period of crystalline lattice arrangement is longer; transition from the crystalline structure of intrinsic nickel at a relevant temperature is greater, and/or crystalline distortion due to stress is greater, in comparison with the state when the crystallinity of nickel is high. The best example of “lower crystallinity” is an amorphous state.

Therefore, it can be said from the above that the platinum-containing nickel layer 22 should more preferably be deposited so that it is rendered into the amorphous state on the end face on the silicon layer side (the face 22a of the platinum-containing nickel layer 22 in contact with the top face 16a of the gate electrode 16 and the top faces 19a of the high-concentration impurity diffused regions 19).

In the step of depositing the platinum-containing nickel layer 22, the platinum-containing nickel layer 22 is deposited by an in-situ sputtering method within the same vacuum apparatus as the one in which the pretreatment is performed before deposition of the platinum-containing nickel layer 22 (the step of removing the natural oxide film).

This makes it possible to prevent reoxidation of the top face 16a of the gate electrode 16 and the top faces 19a of the high-concentration impurity diffused regions 19, and hence to form a nickel mono-silicide layer 24 having a flatter shape (see FIG. 3).

More specifically, the platinum-containing nickel layer 22 is deposited so as to cover the top face 16a of the gate electrode 16 and the top faces 19a of the high-concentration impurity diffused regions 19 by a parallel plate sputtering method in which a platinum-containing nickel layer is used as a target (e.g. nickel with a platinum content of 20% or less), and a target DC power is provided that is 500 W or more and 2500 W or less. The distance between the target and the substrate 11 can be set to a range of 200 to 300 mm, for example.

By using the film formation conditions described above, it is made possible to form the platinum-containing nickel layer 22 such that the crystallinity of nickel is lower near the interfaces with the gate electrode 16 and the high-concentration impurity diffused regions 19. As a result, the nickel mono-silicide layer 24 has a very flat surface.

Further, by depositing the platinum-containing nickel layer 22 by a parallel plate sputtering method using the film formation conditions described above, the platinum-containing nickel layer 22 can be deposited so as to contain silicon (silicon in the high-concentration impurity diffused regions 19 is caused to migrate into the platinum-containing nickel layer 22 by collision of sputtered atoms), and the content of silicon can be made greater in a portion close to the gate electrode 16 and the high-concentration impurity diffused regions 19 than in a portion remote from the gate electrode 16 and the high-concentration impurity diffused regions 19.

Thus, a nickel mono-silicide layer 24 (see FIG. 3) can be formed more stably without causing disilicidation of nickel, by the heat treatment in the process shown in FIG. 3 and to be described later.

The silicon content of the platinum-containing nickel layer 22 on the surface side thereof is more preferably 0%.

Further, by depositing the platinum-containing nickel layer 22 by a parallel plate sputtering method using the film formation conditions described above, the platinum content can be made smaller in a portion close to the gate electrode 16 and the high-concentration impurity diffused regions 19 than in a portion remote from the gate electrode 16 and the high-concentration impurity diffused regions 19.

Thus, the nickel mono-silicide layer 24 can be formed more stably without causing disilicidation of nickel, by the heat treatment in the process shown in FIG. 3 and to be described later.

The platinum content is more preferably 0% in the vicinity of the interface with the gate electrode 16 and the high-concentration impurity diffused regions 19.

In the step of depositing the platinum-containing nickel layer 22, the platinum-containing nickel layer 22 may be deposited so as to cover the top face 16a of the gate electrode 16 and the top faces 19a of the high-concentration impurity diffused regions 19 without heating the substrate 11 at the same time during the deposition. (This shows that, during the deposition, a stage on which wafer is placed is neither heated nor cooled. Patent Document 1 (referred in the background of the invention) describes a configuration of a film formation apparatus in which heating is performed during the deposition. Thus, in a conventional sputtering method, the substrate 11 is heated in order to improve the coverage of a deposited film to the substrate 11.)

In other words, the heating of the substrate 11 is intentionally ceased or stopped in the first embodiment of the invention. Stoppage of heating the substrate 11 is effective to firstly promote, amorphization of nickel in the vicinity of the interface with the gate electrode 16 and the high-concentration impurity diffused regions 19. As sputtering progresses thereafter, the substrate 11 absorbs kinetic energy of sputtered particles and the temperature of the substrate 11 is raised. Thus, crystallization of nickel sputtered progresses after the raise of temperature. This makes it possible to render the nickel mono-silicide layer 24 flat.

In the process shown in FIG. 3, formation of the nickel mono-silicide layer 24 is performed (corresponding to step S07 in the flowchart of FIG. 6).

Specifically, in the process shown in FIG. 3, the nickel mono-silicide layer 24 is formed by causing nickel mono-silicidation to occur at the interface between the platinum-containing nickel layer 22 and the gate electrode 16 and high-concentration impurity diffused regions 19 shown in FIG. 2 by heating (heat-treating) the substrate 11 to 350° C. or more and 500° C. or less.

However, a platinum-containing nickel layer 22-1 (a portion of the platinum-containing nickel layer 22 shown in FIG. 2 remote from the gate electrode 16 and high-concentration impurity diffused regions 19 (un-reacted portion)) remains on the nickel mono-silicide layer 24, as illustrated in FIG. 3 without being transformed into the nickel mono-silicide layer 24.

More specifically, the substrate 11 is subjected to a heat treatment by a lamp annealing method. In this case, the annealing time can be set to a range of 10 to 90 seconds.

In this manner, the nickel mono-silicide layer 24 can be obtained, having a uniform surface and a smooth interface with the gate electrode 16 and high-concentration impurity diffused regions 19 which are formed of a silicon layer.

Subsequently, in the process shown in FIG. 4, the step of removing the platinum-containing nickel layer 22-1 which has not been transformed into the nickel mono-silicide layer 24 is performed (corresponding to step S09 in the flowchart of FIG. 6). This means that in the process shown in FIG. 4, the platinum-containing nickel layer 22-1 shown in FIG. 3 is removed.

Specifically, the platinum-containing nickel layer 22-1 is removed by wet etching using an etchant capable of selectively removing the platinum-containing nickel layer 22-1.

This etching brings about exposure of the surface 24a of the nickel mono-silicide layer 24, the top face 12a of the element isolation region 12, and the surface of the sidewall insulating film 18.

In the process shown in FIG. 5, an interlayer insulating film (e.g. a silicon oxide film (SiO₂ film)) 26 is formed by a known method, so as to cover the top face of the structure shown in FIG. 4 and is flattened so as to form a flattened top face 26a.

Subsequently, contact plugs 27 are formed by a known method. As shown in FIG. 5, the contact plugs 27 pass through the interlayer insulating film 26 and their lower ends of the contact plugs 27 are in contact with the nickel mono-silicide layer 24. Thus, the contact plugs 27 are electrically connected to the high-concentration impurity diffused regions 19 via the nickel mono-silicide layer 24 of a low resistance value. Accordingly, this structure is effective to reduce contact resistance between the contact plugs 27 and the high-concentration impurity diffused regions 19.

Although not shown in FIG. 5, after formation of the contact plugs 27, a plurality of other interlayer insulating films may be successively stacked on the top face 26a of the interlayer insulating film 26 shown in FIG. 5, if necessary, and wirings or vias may be formed in these interlayer insulating films to manufacture the semiconductor device 10 according to the first embodiment.

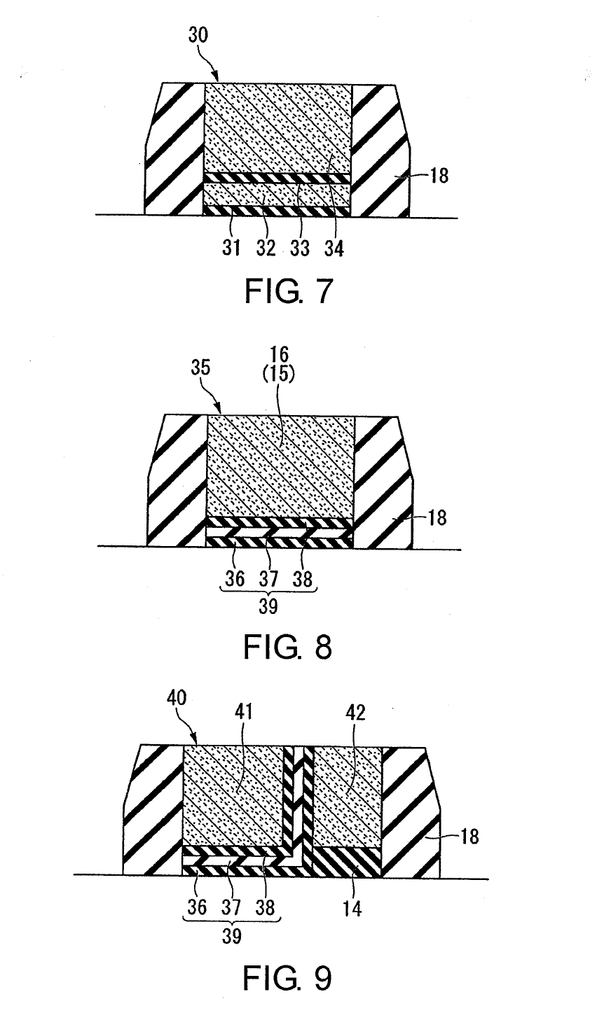

FIGS. 7 to 9 show principal parts of MIS transistors having a charge storage structure, respectively. In FIGS. 7 to 9, similar components to those of the structure shown in FIG. 1 are indicated by the same reference numerals. Likewise, in FIG. 9, similar components to those of the structure shown in FIG. 8 are indicated by the same reference numerals.

In the above-described processes to form the MIS transistor 20 shown in FIG. 1, MIS transistors 30, 35, 40 may be formed which each have a gate insulating film of a charge storage structure as shown in FIGS. 7 to 9.

The MIS transistor 30 shown in FIG. 7 has a floating gate structure in which a tunnel oxide film 31, a floating gate 32, an oxide insulating film 33, and a control gate 34 formed of a polysilicon film are successively stacked.

The MIS transistor 35 shown in FIG. 8 has a charge trap film 39 (ONO structure) in which a silicon oxide film 36 (SiO₂ film), a silicon nitride film 37 (SiN film), and a silicon oxide film 38 (SiO₂ film) are successively stacked. On the charge trap film 39 of the ONO structure, a gate electrode 16 is laminated.

The MIS transistor 40 shown in FIG. 9 has a double gate structure which has a charge trap film 39, a control gate 41 on the charge trap film 39, together with a memory gate 42 arranged on a gate insulating film 14. The charge trap film 39 is identical in structure with that illustrated in FIG. 8.

At any rate, the MIS transistors 30, 35, 40 shown in FIGS. 7 to 9 are each operable as a memory element.

Thus, according to the method of manufacturing the semiconductor device according to the first embodiment, the platinum-containing nickel layer 22 is deposited on the silicon layer (the gate electrode 16 and the high-concentration impurity diffused regions 19) and is subjected to heat treatment to form the nickel silicide layer 24 at the interface.

The use of the platinum-containing nickel layer 22 makes it possible to control the silicide reaction, and consequently makes it possible to form a nickel mono-silicide layer 24 having a low resistance value. In this event, the nickel mono-silicide layer 24 is formed by preventing phase transition to a nickel di-silicide phase (is thermally stable but poor in surface flatness), and by transforming the di-nickel silicide having a high resistance value into mono silicide as much as possible.

When depositing the platinum-containing nickel layer 22 on the silicon layer (the gate electrode 16 and the high-concentration impurity diffused regions 19), the platinum-containing nickel layer 22 is formed so that the crystallinity of nickel is rendered lower in a portion closer to the silicon layer.

For example, it is assumed that the platinum-containing nickel layer 22 is formed in a state exhibiting high crystallinity of nickel at the interface with the silicon layer. In this case, a difference may occur in growth rates that are dependent on crystal orientation in the course of silicidation reaction by heating of the substrate 11, possibly resulting in deterioration of flatness of the nickel mono-silicide layer thus formed.

In contrast, the platinum-containing nickel layer 22 according to the invention is deposited so that the crystallinity of nickel is rendered lower at least in a portion close to the silicon layer. This shows that the nickel mono-silicide layer 24 can keep a favorable surface flatness even after the silicidation reaction caused by heating the substrate 11. As a result, it is possible to form, on the silicon layer, the nickel mono-silicide layer 24 which has a low resistance value and a favorable surface flatness.

The first embodiment has been described about an example in which the platinum-containing nickel layer 22 is deposited so as to cover the silicon layer of both the high-concentration impurity diffused regions 19 (source/drain regions) and the gate electrode 16 of the MIS transistor 20 in the step of depositing the platinum-containing nickel layer 22. However, the platinum-containing nickel layer 22 may be deposited to cover the silicon layer of either the high-concentration impurity diffused regions 19 or the gate electrode 16. This case can also obtain the same effects as the method of manufacturing the semiconductor device 10 according to the first embodiment.

### Second Embodiment

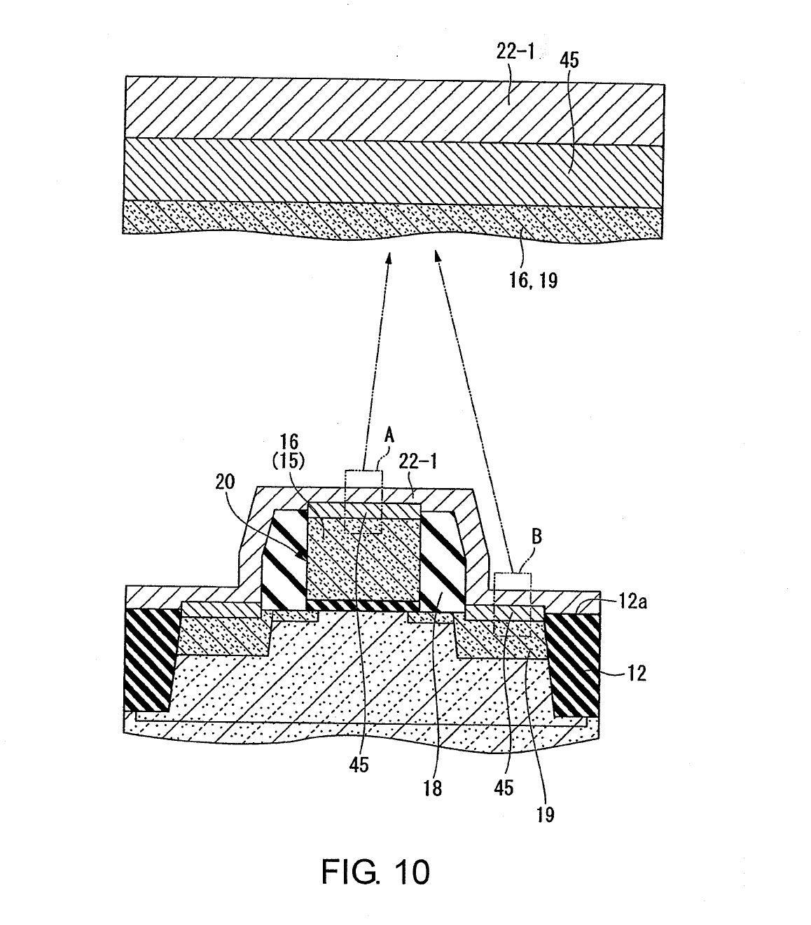

FIGS. 10 to 12 show manufacturing processes of a semiconductor device according to a second embodiment of the invention. FIG. 10 is a cross-sectional view for explaining a process of forming a di-nickel silicide layer 45 obtained by low-temperature annealing the platinum-containing nickel layer 22 deposited in the MIS transistor 20 shown in FIG. 2. Specifically, the MIS transistor 20 illustrated in FIG. 10 has the di-nickel silicide layer 45 and a platinum-containing nickel layer 22-1 left on the di-nickel silicide layer 45. Furthermore, in an enlarged cross section of the encircled regions A and B in the MIS transistor 20, the di-nickel silicide layer 45 is formed on the silicon layer 16, 19 and the platinum-containing nickel layer 22-1 remains on the di-nickel silicide layer 45.

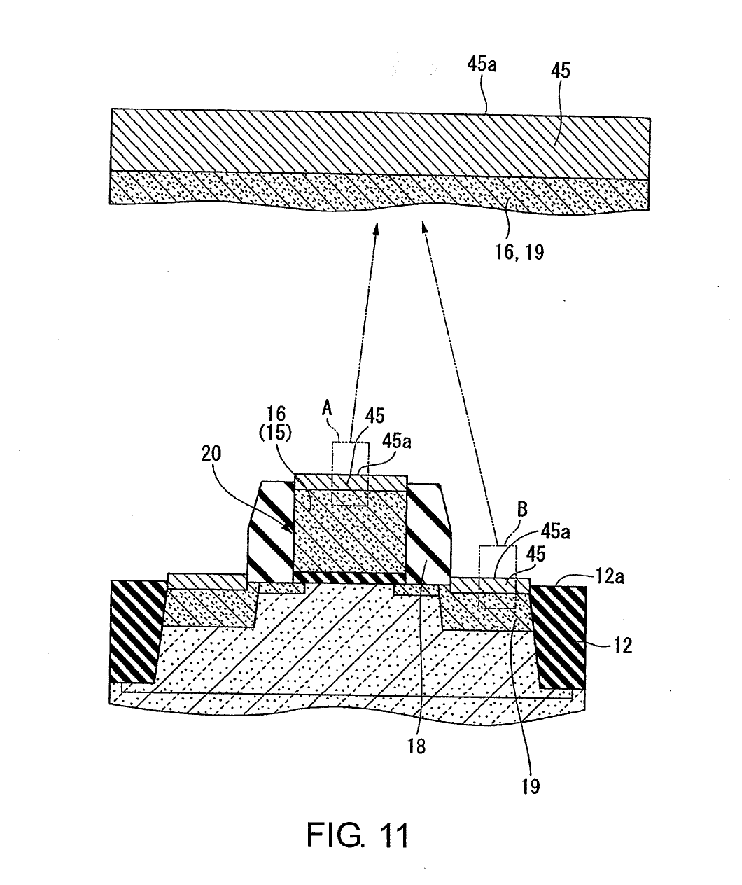

FIG. 11 is a cross-sectional view for explaining a process to remove the remaining platinum-containing nickel layer 22, and illustrates a cross section of the MIS transistor 20 in which the di-nickel silicide layer 45 is formed. In an enlarged cross section of the encircled regions A and B in the MIS transistor 20, only the di-nickel silicide layer 45 is left by removing the platinum-containing nickel layer 22.

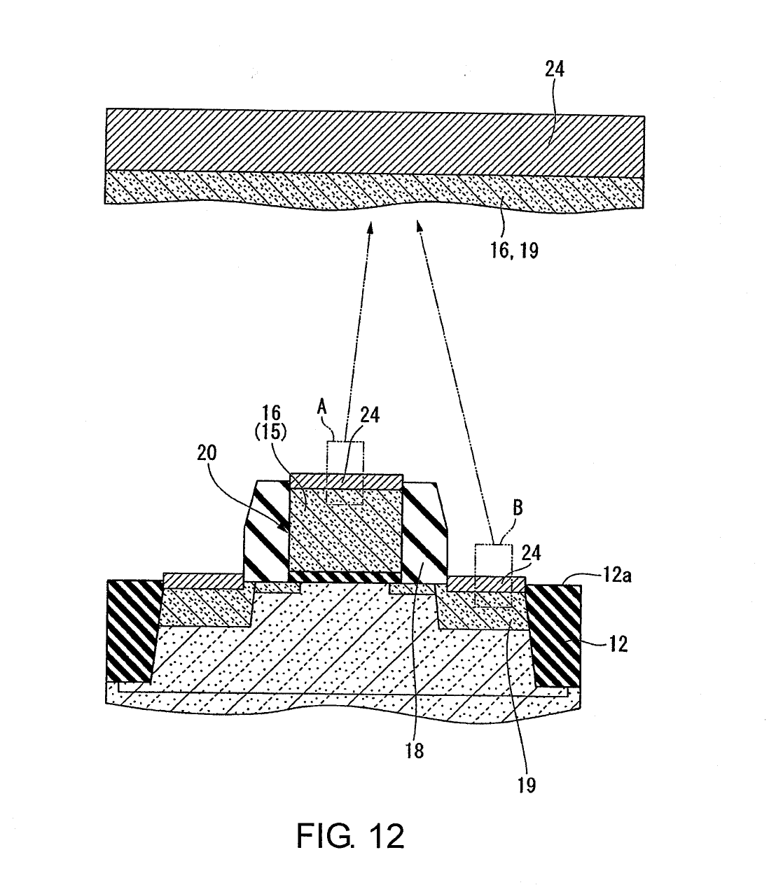

FIG. 12 is a cross-sectional view for explaining a process to form a nickel mono-silicide layer 24, and illustrates a cross section of the MIS transistor 20 in which the nickel mono-silicide layer 24 is formed. In an enlarged cross section of the encircled regions A and B in the MIS transistor 20, the nickel mono-silicide layer 24 is formed by transforming the di-nickel silicide layer 45 illustrated in FIG. 11.

In FIGS. 10 to 12, similar components as those of the structure shown in FIGS. 1 to 4 are assigned with the same reference numerals.

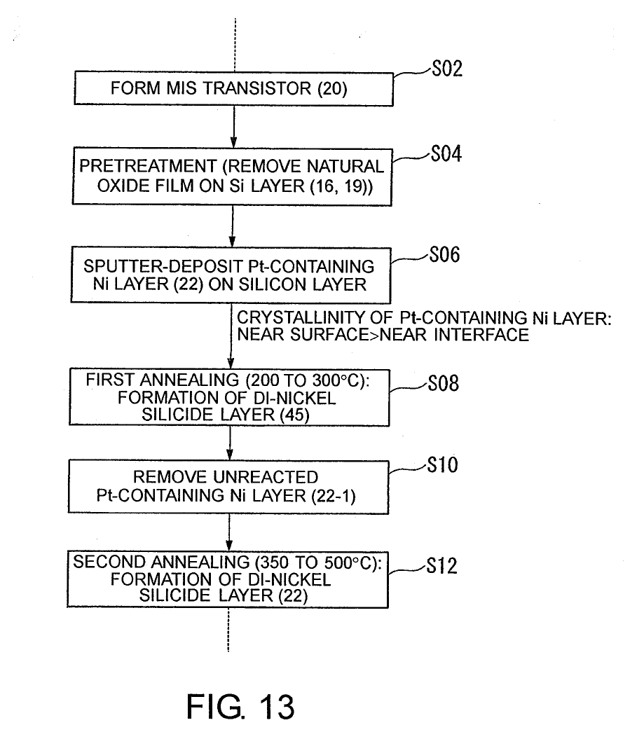

FIG. 13 is a flowchart showing some steps of a method of manufacturing a semiconductor device according to the second embodiment of the invention, from the steps of forming a MIS transistor to the step of forming a di-nickel silicide layer.

Referring principally to FIGS. 10 to 13, the method of manufacturing the semiconductor device 10 according to the second embodiment of the invention will be described.

Firstly, the step of forming the MIS transistor 20 shown in FIG. 1 and described in the first embodiment (corresponding to step S02 shown in the flowchart of FIG. 13) is performed.

Subsequently, the structure shown in FIG. 2 is formed by performing pretreatment (corresponding to step S04 in the flowchart of FIG. 13) before the step of depositing the platinum-containing nickel layer 22 shown in FIG. 2 and described in the first embodiment. Thereafter, the step of depositing the platinum-containing nickel layer 22 (corresponding to step S06 in the flowchart of FIG. 13) is performed.

In the process shown in FIG. 10, the step of forming a di-nickel silicide layer 45 is performed by first annealing (namely, low-temperature annealing) (corresponding to step S08 in the flowchart of FIG. 13).

Specifically, before the step of forming the nickel mono-silicide layer 24, the substrate 11 is heated at a lower temperature than in the step of forming the nickel mono-silicide layer 24, whereby a di-nickel silicide layer 45 is formed at the interface between the platinum-containing nickel layer 22 shown in FIG. 2 and each of the gate electrode 16 (silicon layer) and the high-concentration impurity diffused regions 19 (silicon layer).

More specifically, the substrate 11 is heated by a lamp annealing method to a temperature 200° C. or more and 300° C. or less. The annealing time can be set within a range of 10 to 90 seconds, for example.

After this process, the platinum-containing nickel layer 22-1 is left on the di-nickel silicide layer 45 without being transformed to the di-nickel silicide layer 45 and is located at the portion of the platinum-containing nickel layer 22 remote from the gate electrode 16 and high high-concentration impurity diffused regions 19. Thus, the platinum-containing nickel layer 22-1 remains as un-reacted portion on the di-nickel silicide layer 45.

Subsequently, in the process shown in FIG. 11, the step of removing the platinum-containing nickel layer 22-1 which has not been transformed to the di-nickel silicide layer 45 is performed (corresponding to step S10 in the flowchart of FIG. 13) before the step of forming a nickel mono-silicide layer 24.

Specifically, the remaining platinum-containing nickel layer 22-1 is removed by wet etching using an etchant capable of selectively removing the platinum-containing nickel layer 22-1.

As a result, the surface 45a of the di-nickel silicide layer 45, the top face 12a of the element isolation region 12, and the surface of the sidewall insulating film 18 are exposed.

Subsequently, in the process shown in FIG. 12, the step of forming a nickel mono-silicide layer 24 by second annealing (high-temperature annealing) is performed (corresponding to step S12 in the flowchart of FIG. 13).

Specifically, the nickel mono-silicide layer 24 is formed by heating the substrate 11 to a temperature of 350° C. or more and 500° C. or less so that the di-nickel silicide layer 45 is nickel mono-silicidated.

More specifically, the substrate 11 is heat treated by a lamp annealing method. The annealing time can be set within a range of 10 to 90 seconds, for example.

As a result, a nickel mono-silicide layer 24 can be obtained, which has a uniform surface and a flat interface with the gate electrode 16 and high-concentration impurity diffused regions 19 both of which are formed of a silicon layer.

After that, the same process as the one shown in FIG. 5 and described in the first embodiment is performed to manufacture the semiconductor device 10 shown in FIG. 5.

According to the method of manufacturing the semiconductor device according to the second embodiment, the silicidation annealing is performed in twice. Specifically, the first annealing is performed at such a low temperature that a di-nickel silicide layer 45 can be formed, and then the second annealing is performed at such a high temperature that a nickel mono-silicide layer 24 can be formed. This makes it possible form a nickel mono-silicide layer 24 stably and without causing di-silicidation.

After the first annealing, the un-reacted platinum-containing nickel layer 22-1 is removed before the second annealing, whereby it is made possible to form the nickel mono-silicide layer 24 even more stably without causing di-silicidation.

When it is aimed to form a flat nickel mono-silicide layer 24 having a low resistance in as small a number of steps as possible, it is desirable to select the method of manufacturing a semiconductor device according to the first embodiment, whereas when it is aimed to form a flat nickel mono-silicide layer 24 as stably as possible, it is desirable to select the method of manufacturing a semiconductor device according to the second embodiment.

While the invention has been described with reference to preferred embodiments thereof, the invention is not limited these specific embodiments, and various changes and variations may be made without departing from the spirit and scope of the invention as defined in the following claims.

The invention is applicable to methods of manufacturing semiconductor devices other than MIS transistors exemplified above.

What is claimed is:

1. A method of manufacturing a semiconductor device comprising:
depositing a platinum-containing nickel layer that covers a silicon layer on a substrate and that has crystallinity lower in a portion of the platinum-containing nickel layer close to the silicon layer than in a portion remote from the silicon layer; and
heating the substrate after the deposition of the platinum-containing nickel layer.

2. The method of manufacturing a semiconductor device according to claim 1, wherein the heating the substrate comprises:
forming a nickel mono-silicide layer at the interface between the silicon layer and the platinum-containing nickel layer.

3. The method of manufacturing a semiconductor device according to claim 1, wherein the depositing the platinum-containing nickel layer comprises:
depositing the platinum-containing nickel layer such that the end face of the platinum-containing nickel layer on the side of the silicon layer is amorphous.

4. The method of manufacturing a semiconductor device according to claim 1, wherein the depositing the platinum-containing nickel layer comprises:
preparing platinum-containing nickel as a target; and
depositing the platinum-containing nickel layer so as to cover the silicon layer by the use of a parallel plate sputtering method by supplying the target with DC power of 500 W or more and 2500 W or less.

5. The method of manufacturing a semiconductor device according to claim 4, wherein the depositing the platinum-containing nickel layer uses, as the target, the nickel having a platinum content of 20% or less of the total.

6. The method of manufacturing a semiconductor device according to claim 1, wherein the depositing the platinum-containing nickel layer comprises:
depositing the platinum-containing nickel layer containing silicon, so that the silicon content is greater in a portion of the platinum-containing nickel layer close to the silicon layer than in a portion remote from the silicon layer.

7. The method of manufacturing a semiconductor device according to claim 1, wherein the depositing the platinum-containing nickel layer comprises:
depositing the platinum-containing nickel layer so that a platinum content is smaller in a portion of the platinum-containing nickel layer close to the silicon layer than in a portion remote from the silicon layer.

8. The method of manufacturing a semiconductor device according to claim 1, wherein the depositing the platinum-containing nickel layer comprises:
depositing the platinum-containing nickel layer without heating the substrate so as to cover the silicon layer.

9. The method of manufacturing a semiconductor device according to claim 1, further comprising:
before the depositing the platinum-containing nickel layer, exposing the silicon layer on the substrate by removing a silicon oxide film formed on the surface of the silicon layer.

10. The method of manufacturing a semiconductor device according to claim 9, wherein the exposing the silicon layer to the depositing the platinum-containing nickel layer are performed within the same vacuum apparatus.

11. The method of manufacturing a semiconductor device according to claim 10, wherein the exposing the silicon layer comprises:
removing the silicon oxide film formed on the silicon layer, by RF etching using argon gas to expose the silicon layer.

12. The method of manufacturing a semiconductor device according to claim 10, wherein the exposing the silicon layer comprises:
reacting the silicon oxide film with CF₄ gas; and
removing a reaction product thus produced to expose the silicon layer.

13. The method of manufacturing a semiconductor device according to claim 2, wherein the forming the nickel mono-silicide layer comprises:
heating the substrate to 350° C. or more and 500° C. or less.

14. The method of manufacturing a semiconductor device according to claim 2, further comprising:
after the step of forming the nickel mono-silicide layer, removing the portion of the platinum-containing nickel layer which has not been transformed into the nickel mono-silicide layer.

15. The method of manufacturing a semiconductor device according to claim 2, further comprising:
after the depositing the platinum-containing nickel layer and before the forming the nickel mono-silicide layer, heating the substrate to form a di-nickel silicide layer at the interface between the silicon layer and the platinum-containing nickel layer.

16. The method of manufacturing a semiconductor device according to claim 15, wherein the forming the di-nickel silicide layer comprises:
heating the substrate at a lower temperature than in the forming the nickel mono-silicide layer.

17. The method of manufacturing a semiconductor device according to claim 15, wherein the forming the di-nickel silicide layer comprises:
heating the substrate to a temperature of 200° C. or more and 300° C. or less.

18. The method of manufacturing a semiconductor device according to claim 15, further comprising:
after the forming and di-nickel silicide layer and before the forming the nickel mono-silicide layer, removing a portion of the platinum-containing nickel layer which has not been transformed into the di-nickel silicide layer.

19. The method of manufacturing a semiconductor device according to claim 1, further comprising:
before the depositing the platinum-containing nickel layer, forming a MIS transistor on the substrate,
wherein the depositing the platinum-containing nickel layer comprises:
depositing the platinum-containing nickel layer so as to cover either the source/drain region or the gate electrode of the MIS transistor, or the silicon layer forming both the source/drain region and the gate electrode of the MIS transistor.

20. The method of manufacturing a semiconductor device according to claim 19, wherein the forming the MIS transistor comprises:
forming a MIS transistor having a gate insulating film including a charge storage structure.
